(19) United States
(12) Patent Application Publication
(10) Pub. No.: US 2026/0066232 A1
(43) Pub. Date: Mar. 5, 2026

(54) PLASMA PROCESSING APPARATUS AND PLASMA PROCESSING METHOD

(71) Applicant: HITACHI HIGH-TECH CORPORATION, Minato-ku, Tokyo (JP)

(72) Inventors: Sylvan KOYAGURA, Tokyo (JP); Shota TAHARA, Tokyo (JP); Haixiang HUANG, Tokyo (JP); Hiroshige UCHIDA, Tokyo (JP); Kenichi KUWAHARA, Tokyo (JP)

(21) Appl. No.: 18/689,261

(22) PCT Filed: May 19, 2023
(86) PCT No.: PCT/JP2023/018800

§ 371 Date: Mar. 5, 2024

(51) Int. Cl. H01J 37/32

(52) U.S. Cl. CPC H01J 37/32311; H01J 37/32935; H01J 2237/24507; H01J 2237/334

(57) ABSTRACT

Aspects relate to providing a plasma processing technique that is capable of facilitating uniform etching results in low-power microwave plasma processing applications. A plasma processing apparatus includes a control unit configured to cause a microwave power supply to output a first microwave pulse having a first power and a first duty ratio to produce a uniformly distributed plasma in a plasma processing chamber; the microwave power supply to output a second microwave pulse having a second power which is less than the first power and a second duty ratio which is greater than the first duty ratio; a RF bias power supply to apply a wafer bias voltage with respect to a substrate stage; and the microwave power supply and the RF bias power supply to cease output of the second microwave pulse and the wafer bias voltage.

### TECHNICAL FIELD

The present disclosure relates to a plasma processing apparatus and a plasma processing method.

### BACKGROUND ART

Conventionally, techniques are known for processing the surface of a semiconductor device by etching it with plasma. As an example, the Electron Cyclotron Resonance (ECR) method is an example of one technique that can be used to etch semiconductor devices using plasma. In the ECR technique, plasma is generated by microwaves in a vacuum container to which an external magnetic field is applied. Electrons perform cyclotron motion due to the magnetic field, and by creating resonance between the frequency of the magnetic field with the frequency of the microwaves, plasma can be generated.

In this technique, high-frequency power is applied to a sample (for example, a wafer) in a substantially sinusoidal continuous waveform in order to accelerate ions incident on the semiconductor device. The high-frequency power applied to the sample is called a high-frequency bias. Halogen gases such as chlorine and fluorine are widely used as the gas to produce plasma. Etching progresses by the reaction between the radicals and ions generated by the plasma with the material of the sample. By performing plasma control to select the radical species and amount of ions, high-precision etching can be achieved.

Japanese Unexamined Patent Application Publication No. 2020-17565 (Patent Document 1) is one example of a conventional plasma etching technique.

Patent Document 1 discloses “Provided is a technique that can control a process with high precision. The plasma processing apparatus 1 comprises a processing chamber 104 in which a sample (wafer 112) is plasma-processed, a first high-frequency power source (electromagnetic wave generation power source 109) for supplying a first high-frequency power 161 for generating plasma, a sample stage (sample placement electrode 111) on which the sample is placed, and a second high-frequency power supply (high-frequency bias power supply 114) that supplies a second high-frequency power 162 to the sample stage. Furthermore, the device also includes a pulse generation unit 121 that generates a first pulse for time-modulating the first high-frequency power 161 and a second pulse for time-modulating the second high-frequency power 162. The first pulse has an off period, a first period, and a second period, where the amplitude of the first period is a finite value and the amplitude of the second period is greater than that of the first period. The second pulse is an on period during the second period.”

### CITATION LIST

### Patent Literature [PTL 1]

Japanese Unexamined Patent Application Publication No. 2020-17565

### SUMMARY OF INVENTION

### Technical Problem

Low-power plasma etching that uses lower power microwaves is one type of plasma etching that has demand for a range of applications. By using low-power microwaves, a gentle plasma can be created that allows for increased etching selectivity while reducing damage to the substrate in comparison with high-power plasma etching. Low-power plasma etching has applications for microfabrication, surface modification and medical device production.

When performing plasma etching using low-power microwaves, however, the produced plasma has relatively low density, and does not spread out evenly to the outer periphery of the processing chamber, resulting in a non-uniform plasma distribution. Etching performed with such a low-density, nonuniform plasma distribution leads to nonuniform etching results on the sample surface.

Patent Document 1 discloses a technique of performing plasma processing in which a microwave output cycle has an off period and two on periods, where the microwave output in the second on period has a greater amplitude (microwave power) than the microwave output in the first on period, and a high frequency bias voltage is applied during the second on period. According to the technique of Patent Document 1, it is possible to prevent isotropic etching resulting from a period in which high power microwaves are applied while the high frequency bias voltage is off.

Patent Document 1, however, does not consider the challenges of nonuniform etching resulting from nonuniform plasma distribution in low-power microwave processing applications.

Accordingly, it is an object of the present disclosure to provide a plasma processing technique that is capable of facilitating uniform etching results in low-power microwave plasma processing applications.

### Solution to Problem

One representative example of the present disclosure relates to a plasma processing apparatus comprising: a plasma processing chamber; a substrate stage disposed within the plasma processing chamber and configured to support a substrate; a microwave power supply coupled to the plasma processing chamber and configured to generate a microwave signal; a RF bias power supply coupled to the substrate stage and configured to generate an RF bias signal; and a control unit configured to control the microwave power supply and the RF bias power supply; wherein the control unit causes: the microwave power supply to output, in a first time period, a first microwave pulse having a first power and a first duty ratio to produce a plasma that achieves a plasma density distribution criterion in the plasma processing chamber; the microwave power supply to output, in a second time period subsequent to the first time period, a second microwave pulse having a second power which is less than the first power and a second duty ratio which is greater than the first duty ratio; the RF bias power supply to apply, in the second time period, a wafer bias voltage with respect to the substrate stage; and the microwave power supply and the RF bias power supply to cease output of the second microwave pulse and the wafer bias voltage for a third time period subsequent to the second time period.

### ADVANTAGEOUS EFFECTS OF INVENTION

According to the present disclosure it is possible to provide a plasma processing technique that is capable of facilitating uniform etching results in low-power microwave plasma processing applications.

Problems, configurations, and effects other than those described above will be made clear by the following description in the embodiments for carrying out the invention.

### BRIEF DESCRIPTION OF DRAWINGS

FIG. 1 is a schematic configuration diagram of a longitudinal section of an ECR type microwave plasma processing apparatus according to the embodiments of the present disclosure.

FIG. 2 is a flowchart illustrating an example flow of a plasma processing method according to the embodiments of the present disclosure.

FIG. 3 is a diagram illustrating a graph of microwave power level settings and bias power level settings according to the embodiments of the present disclosure.

FIG. 4 is a diagram illustrating an example of a non-uniform plasma distribution in a plasma processing chamber.

FIG. 5 is a diagram illustrating an example of a uniform plasma distribution in a plasma processing chamber.

FIG. 6 is a table illustrating an example of plasma processing parameters and corresponding plasma processing results, according to the embodiments of the present disclosure.

### DESCRIPTION OF EMBODIMENT(S)

Herein, embodiments of the present invention will be described with reference to the Figures. It should be noted that the embodiments described herein are not intended to limit the invention according to the claims, and it is to be understood that each of the elements and combinations thereof described with respect to the embodiments are not strictly necessary to implement the aspects of the present invention.

Various aspects are disclosed in the following description and related drawings.

Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Further, many aspects are described in terms of sequences of actions to be performed by, for example, elements of a computing device. It will be recognized that various actions described herein can be performed by specific circuits (e.g., an application specific integrated circuit (ASIC)), by program instructions being executed by one or more processors, or by a combination of both. Additionally, the sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter.

Hereinafter, a detailed description of the embodiments of the present disclosure will be described with reference to the Figures.

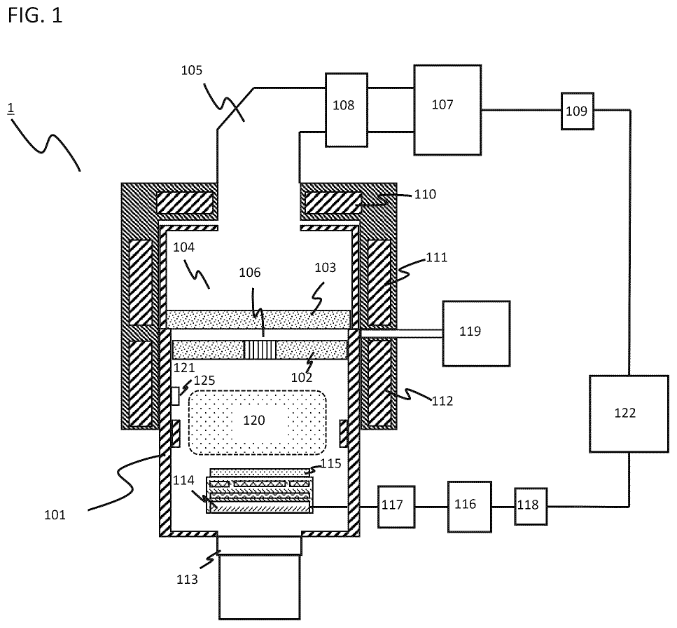

Turning now to the Figures, a schematic configuration diagram of a longitudinal section of an ECR type microwave plasma processing apparatus according to the embodiments of the present disclosure will be described with reference to FIG. 1.

FIG. 1 is a schematic configuration diagram of a longitudinal section of an ECR (Electron Cyclotron Resonance) type microwave plasma processing apparatus (hereinafter referred to as a plasma processing apparatus) according to the embodiments of the present disclosure. In embodiments, each component of the plasma processing apparatus 1, such as the processing chamber 121, the substrate stage 114, and the wafer 115, may have an axially symmetrical shape such as a cylinder, column, or disk.

In FIG. 1, an evacuation device 113 is connected to the lower portion of the processing chamber 121 inside the vacuum chamber 101 of the plasma processing apparatus 1. A shower plate 102 and a quartz top plate 103 are arranged in the upper part of the inside of the processing chamber 121. The shower plate 102 includes a plurality of holes. A plasma etching gas supplied from the gas supply device 119 is introduced into the processing chamber 121 through the holes of the shower plate 102. A quartz top plate 103 is arranged on the shower plate 102, and a gap 106 for gas supply is provided between the shower plate 102 and the quartz top plate 103. The quartz top plate 103 allows transmission of electromagnetic waves from above and hermetically seals the upper portion of the processing chamber 121.

A substrate stage 114 is arranged below the processing chamber 121 so as to face the quartz top plate 103. The substrate stage 114 supports a wafer 115 (that is, a sample) placed thereon.

A cavity resonator 104 is arranged on the quartz top plate 103. The upper portion of the cavity resonator 104 is open, and is connected to a waveguide 105 that consists of a waveguide transformer that combines a vertical waveguide extending in the vertical direction with a bent portion that bends the direction of electromagnetic waves by 90 degrees. The waveguide 105 and the like serve as oscillation waveguides for propagating electromagnetic waves, and at the end portion of the waveguide 105, a microwave power supply 107 for plasma generation is connected via a tuner 108.

The microwave power supply 107 is a power source for plasma generation, and oscillates electromagnetic waves under the control of the control unit 122. As an example, the microwave power supply 107 may perform microwave oscillation of 2.45 GHz. A microwave oscillated by the microwave power supply 107 propagates through the waveguide 105 and propagates into the processing chamber 121 via the cavity resonator 104, the quartz top plate 103 and the shower plate 102. Magnetic field generation coils 110, 111 and 112 are arranged around the processing chamber 121. The magnetic field generation coils are composed of a plurality of coils and form a magnetic field in the processing chamber 121. High-frequency power oscillated from the microwave power supply 107 generates high-density plasma 120 in the processing chamber 121 due to the interaction between the magnetic field generated by the magnetic field generation coils 110 to 112 and the ECR.

A microwave pulse unit 109 is connected to the microwave power supply 107. A pulse ON signal from the microwave pulse unit 109 enables the microwave power supply 107 to pulse-modulate microwaves at a set repetition frequency. The high-frequency power output from the microwave power supply 107 is called microwave power (hereinafter, also referred to as MW power). The microwave pulse unit 109 may cause the microwave power supply 107 to output, in a first time period, a first microwave pulse having a first power and a first duty ratio to produce a uniformly distributed plasma 120 in the plasma processing chamber 121, and output, in a second time period subsequent to the first time period, a second microwave pulse having a second power which is less than the first power and a second duty ratio which is greater than the first duty ratio. The microwave power supply 107 may cease output of the second microwave pulse for a third time period subsequent to the second time period.

In embodiments, a plasma distribution sensor 125 configured to monitor a plasma density distribution of the plasma 120 may be arranged in the processing chamber 121. This plasma distribution sensor 125 may continuously monitor the plasma density distribution of the plasma 120 in the processing chamber 121. As described herein, the plasma density distribution measurement values collected by the plasma distribution sensor 125 may be used to determine when to cease output of a second microwave pulse and a wafer bias voltage in order to facilitate uniform etching results. In embodiments, the plasma distribution sensor 125 may be implemented using a Langmuir probe configured to measure the plasma density and temperature in the processing chamber 121 by measuring the current collected by a small electrode immersed in the plasma 120, optical emission spectroscopy that uses a spectrometer to analyze the light emitted by the plasma 120 and determine its composition, microwave interferometry that uses microwaves to measure the plasma density by analyzing the interference pattern generated by microwaves passing through the plasma 120, electrostatic probes configured to measure the plasma potential by measuring the voltage between a small electrode and the plasma 120, or the like.

The RF bias power supply 116 generates high frequency power for ion attraction and supplies it to the substrate stage 114. A matching box 117 is connected to the RF bias power supply 116 to match (align) the RF bias. The matching box 117 functions to match the RF bias even when the plasma density is changed by the microwave pulsed oscillations and the plasma impedance fluctuates rapidly. The RF bias power supply 116 may be configured to apply, in the second time period, a wafer bias voltage with respect to the substrate stage 114. The RF bias power supply 116 may cease output of the wafer bias voltage for a third time period subsequent to the second time period.

The control unit 122 is a control device for the plasma processing apparatus 1 and is connected to the microwave power supply 107 and an RF bias power supply (Radio Frequency bias power supply) 116 to control the output of microwave power and RF bias power. In embodiments, the control unit 122 may be configured to control output of the first microwave pulse from the microwave power supply 107, the second microwave pulse from the microwave power supply 107, the wafer bias voltage output by the RF bias power supply 116 with respect to the substrate stage 114, the ON and OFF timings of the microwave pulse unit 109, the frequency and duty ratio of the microwave power supply 107, and the delay time of the microwave power supply 107. Further, the control unit may control the pulse ON and OFF timings in the RF bias pulse unit 118, the repetition frequency and duty ratio of turning on and off of the RF bias power supply 116, the delay time of the RF bias power supply 116, and other parameters of the microwave power supply 107 and the RF bias power supply 116. In addition, the control unit 122 may be configured to control etching parameters such as gas flow rate, processing pressure, coil current, sample stage temperature, etching time, and the like to facilitate desired etching performance.

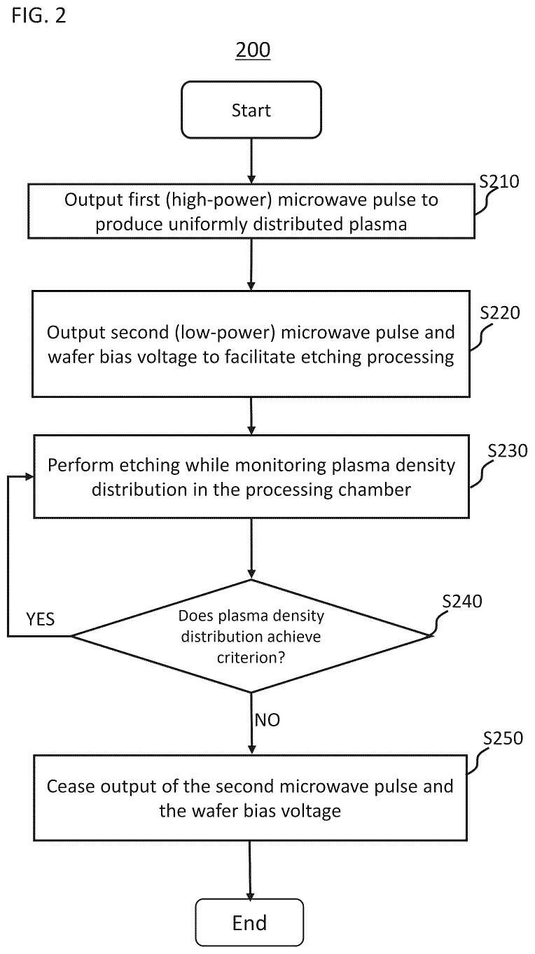

Next, with reference to FIG. 2, an example flow of a plasma processing method according to the embodiments of the present disclosure will be described.

FIG. 2 is a flowchart illustrating an example flow of a plasma processing method 200 according to the embodiments of the present disclosure. The plasma processing method 200 is a process for performing plasma etching of a sample using a plasma processing apparatus such as that illustrated in FIG. 1. As described herein, the sample may include a wafer disposed on the substrate stage at the lower portion of the vacuum container of the plasma processing apparatus 1 illustrated in FIG. 1.

First, at Step S210, the control unit 122 of the plasma processing apparatus 1 causes the microwave power supply 107 to output, in a first time period, a first microwave pulse having a first power and a first duty ratio to produce a dense, uniformly distributed plasma 120 in the plasma processing chamber 121 of the plasma processing apparatus 1. As an example, the first microwave pulse may have a first power of 1500 Watts and a first duty ratio of 5%, but the present disclosure is not limited herein, and the first power and the first duty ratio may be adjusted according to the specifications of the etching application. Here, the first time period refers to the window of time in which the first microwave pulse is output.

In certain embodiments, the first power and the first duty ratio may be set to values that are capable of achieving a desired plasma density distribution as indicated by simulation results. In this way, the first microwave pulse can be used to produce a dense, uniformly distributed plasma 120 in the plasma processing chamber 121 of the plasma processing apparatus 1.

Next, at Step S220, the control unit 122 of the plasma processing apparatus 1 causes the microwave power supply 107 to output, in a second time period subsequent to the first time period, a second microwave pulse having a second power and a second duty ratio, and the RF bias power supply 116 to apply, in the second time period, a wafer bias voltage with respect to the substrate stage 114. Here, the second power is less than the first power of the first microwave pulse, and the second duty ratio is greater than the first duty ratio of the first microwave pulse. For example, the second power may be 300 Watts and the second duty ratio may be 15%. As described above with respect to the first microwave pulse, however, the present disclosure is not limited herein, and the second power and the second duty ratio may be adjusted according to the specifications of the etching application or based on simulation results.

As an example, with reference to a case in which a wafer having a height of 100 mm and a radius of 150 mm is used, the ratio of the second duty ratio of the second microwave pulse with respect to the first duty ratio of the first microwave pulse may be set to a value greater than 1, and the first power of the first microwave pulse and the second power of the second microwave pulse may be set so as to achieve an ion density ratio of the first microwave pulse with respect to the second microwave pulse of 1.48×10¹⁷/0.95×10¹⁷ ions per cubic meter. It should be noted that an ion density ratio of greater than this number may not be sufficient to achieve the desired ignition and plasma processing power for uniform plasma processing.

It should be noted that the second microwave pulse and the wafer bias voltage are applied together in the second time period. For instance, the second microwave pulse and the wafer bias voltage may be applied substantially simultaneously with one another. In this way, efficient etching can be facilitated with respect to the sample. Further, it should be noted that, upon switching from the first microwave pulse to the second microwave pulse having a lower power, the plasma 120 begins to converge toward the center of the plasma processing chamber, and the plasma density distribution decreases. Accordingly, as described herein, aspects of the disclosure relate to performing etching of the sample before the plasma density distribution falls below a predetermined plasma density distribution criterion in order to achieve uniform etching results.

In embodiments, the wafer bias voltage may be associated with a wafer bias delay, and each microwave pulse may be associated with a microwave pulse delay. The microwave pulse delay refers to the time duration that output of a particular microwave pulse is delayed in a pulsed microwave plasma source. The microwave pulse delay may be set relative to the output of another microwave pulse (e.g., the time interval between output of the first microwave pulse and output of the second microwave pulse) or the end of another microwave pulse (e.g., the time interval after the first microwave pulse has ended before the second microwave pulse begins.) In general, the microwave pulse delay time can have an impact on the characteristics of the plasma, such as the plasma density, ion energy, and radical species concentration. Longer delay times between pulses may result in longer periods of no microwave power, which can lead to lower plasma density and reduced etching or deposition rates. Shorter delay times between pulses, on the other hand, can result in higher plasma density, higher ion energy, and increased etching or deposition rates. However, shorter delay times may also result in increased ion bombardment and damage to the substrate or the deposited film. In embodiments, the microwave pulse delay may be represented as a percentage of the time of one processing cycle (e.g., a microwave pulse delay ratio). This microwave pulse delay ratio is the ratio of the delay time of the ON period of a microwave pulse with respect to the total time of one cycle of the microwave modulation pulse.

Wafer bias delay is a parameter that refers to the time duration that output of the wafer bias voltage is delayed in a pulsed microwave plasma source. The wafer bias delay may be set relative to the output of another microwave pulse (e.g., the time interval between output of the first microwave pulse and output of the wafer bias voltage) or the end of another microwave pulse (e.g., the time interval after the first microwave pulse has ended before the wafer bias voltage application begins). In some cases, during the wafer bias delay, the sample may be exposed to a DC bias voltage before plasma is generated. This bias voltage can affect the surface of the substrate, by removing any oxide layers, and creating a clean and activated surface. This can improve the adhesion and the quality of the deposited film, as well as modify the surface chemistry of the substrate. If the wafer bias delay is too long, however, it can lead to excess sputtering of the substrate, which can damage the surface and result in a non-uniform etching profile. On the other hand, if the wafer bias delay is too short, the surface of the substrate may not be properly activated, which can result in poor film quality or adhesion. In embodiments, the wafer bias delay may be represented as a percentage of the time of one processing cycle (e.g., a wafer bias delay ratio). This wafer bias delay ratio is the ratio of the ON period delay time to one cycle of the wafer bias modulation pulse.

According to the research of the inventors of the present disclosure, it was found that delaying output of the second microwave pulse with respect to output of the first microwave pulse by a second microwave pulse delay equal to the first duty ratio (e.g., such that the second microwave pulse begins when the first microwave pulse ends), and delaying output of the wafer bias voltage with respect to output of the first microwave pulse by a wafer bias delay that is greater than or equal to the second microwave pulse delay (e.g., such that the wafer bias voltage is output at the same time or later than the second microwave pulse) achieved etching results associated with a high degree of uniformity. This is because, by initiating plasma processing using the second microwave pulse quickly after uniform plasma has been created using the first pulse, etching can be carried out at the time when the plasma density distribution is at its most uniform state. As an example, in a case that the first duty rate is 30% and the second duty rate is 50%, the second microwave pulse delay may be set to 30% (e.g., equal to the first duty rate) and the wafer bias delay may be set to 30% or more (e.g., greater than or equal to the second microwave pulse).

Next, at Step S230, during the second time period, etching is performed with respect to the sample while the plasma distribution sensor 125 disposed in the plasma processing apparatus 1 continuously monitors the plasma density distribution of the plasma 120. For example, the plasma distribution sensor 125 may measure the plasma density distribution of the plasma 120 in terms of ions per cubic meter, and compare the measured plasma density distribution values with respect to a predetermined plasma density distribution criterion. Here, the plasma density distribution criterion is a benchmark, standard, or reference used to evaluate when the plasma density distribution has decreased below a tolerance threshold. In embodiments, the plasma density distribution criterion may be set as the minimum plasma density distribution value for which satisfactory etching uniformity can be achieved.

As an example, with reference to a case in which a wafer having a height of 100 mm and a radius of 150 mm is used, the plasma density distribution criterion may be set to an ion density ratio of the first microwave pulse with respect to the second microwave pulse of 1.48×10¹⁷/0.95×10¹⁷ ions per cubic meter. This is because, at greater ion density ratios, the ion density may be insufficient to achieve uniform plasma processing. As another example, the plasma density distribution criterion may be set to a value of “0.5×10¹⁷ ions per cubic meter.

Next, at Step S240, in response to determining that the plasma density distribution fails to achieve the plasma density distribution criterion, the plasma processing method 200 may proceed to Step $250. In the case that the plasma density distribution achieves the plasma density distribution criterion, the plasma processing method 200 may return to Step S230, and etching may be continued until the desired etching results are obtained or until the plasma density distribution fails to achieve the plasma density distribution criterion.

Next, at Step S250, the control unit 122 of the plasma processing apparatus 1 causes the microwave power supply 107 and the RF bias power supply 116 to cease output of the second microwave pulse and the wafer bias voltage for a third time period subsequent to the second time period. Here, the third time period corresponds to an off-state. By ceasing output of the second microwave pulse and the wafer bias voltage, the plasma 120 returns to a gas, and etching is no longer performed. In this way, by ceasing output of the second microwave pulse and the wafer bias voltage once the plasma density distribution fails to achieve a desired plasma density distribution criterion, etching that would result in low-uniformity results can be avoided.

According to the plasma processing method 200 described with reference to FIG. 2, by first outputting a high-power microwave pulse to produce a uniformly distributed plasma 120, and then outputting a low-power microwave pulse together with a wafer bias voltage to facilitate etching processing, and ceasing output of the low-power microwave pulse and the wafer bias voltage in response to detecting that the plasma density distribution of the plasma 120 in the plasma processing chamber 121 no longer achieves a predetermined plasma density distribution criterion, etching results associated with high uniformity can be obtained.

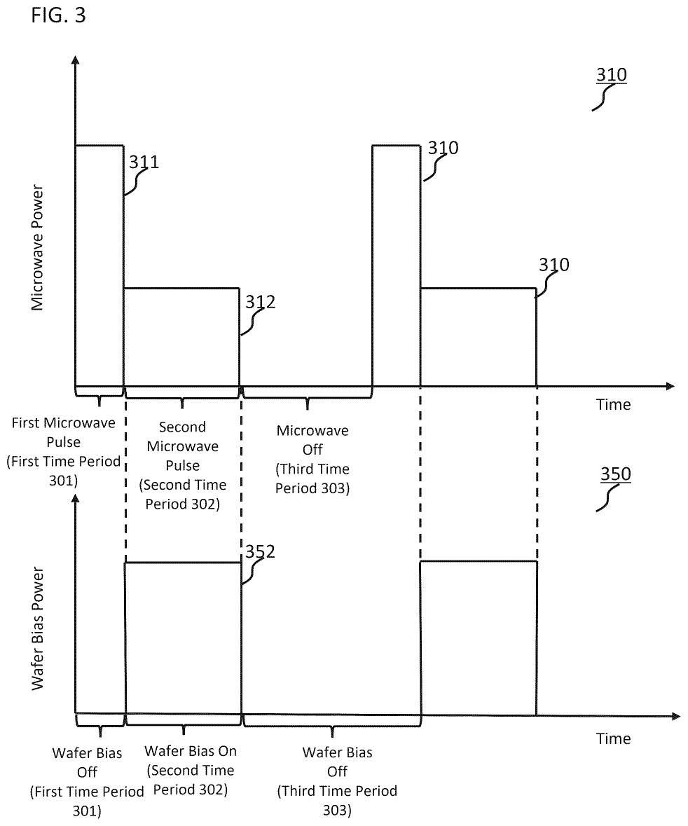

Next, with reference to FIG. 3, the microwave power level settings and bias power level settings according to the embodiments of the present disclosure will be described.

FIG. 3 is a diagram illustrating a graph of microwave power level settings and bias power level settings according to the embodiments of the present disclosure. As described herein, aspects of the present disclosure relate to controlling the power of the microwaves and wafer bias during plasma processing to facilitate high uniformity etching results. FIG. 3 illustrates a microwave power graph 310 and a wafer bias power graph 350 for one cycle of a plasma etching process.

As illustrated in the microwave power graph 310, first, during a first time period 301, the control unit 122 causes the microwave power supply 107 to output a first microwave pulse 311 having a first power and a first duty ratio. The first power and first duty ratio are set to values capable of generating a dense, uniformly distributed plasma 120 in the plasma processing chamber 121 of the plasma processing apparatus. As an example, the first microwave pulse may have a first power of 1500 Watts and a first duty ratio of 5%. As illustrated in the wafer bias power graph 350, it can be seen that during this first time period 301 while the first microwave pulse 311 is being output, no wafer bias is applied.

Next, during a second time period 302 subsequent to the first time period 301, the control unit 122 causes the microwave power supply to perform a discharge switch to switch from the first power to a second power, and output a second microwave pulse 312 having the second power and the second duty ratio. Here, the second power is less than the first power of the first microwave pulse, and the second duty ratio is greater than the first duty ratio of the first microwave pulse. For example, the second power may be 300 Watts and the second duty ratio may be 15%.

As an example, with reference to a case in which a wafer having a height of 100 mm and a radius of 150 mm is used, the ratio of the second duty ratio of the second microwave pulse with respect to the first duty ratio of the first microwave pulse may be set to a value greater than 1, and the first power of the first microwave pulse and the second power of the second microwave pulse may be set so as to achieve an ion density ratio of the first microwave pulse with respect to the second microwave pulse of 1.48×10¹⁷/0.95×10¹⁷ ions per cubic meter. It should be noted that an ion density ratio of greater than this number may not be sufficient to achieve the desired ignition and plasma processing power for uniform plasma processing.

Upon switching from the first microwave pulse to the second microwave pulse having a lower power, the plasma 120 begins to converge toward the center of the plasma processing chamber 121, and the uniformity of the plasma density distribution decreases.

Additionally, in the second time period 302, the RF bias power supply 116 applies a wafer bias voltage 352 at the same time that the second microwave pulse 312 is output by the microwave power supply 107. The simultaneous application of the wafer bias voltage 352 and the second microwave pulse 312 facilitate efficient etching with respect to the sample. In this way, etching is performed while the plasma distribution sensor 125 disposed in the plasma processing apparatus continuously monitors the plasma density distribution of the plasma 120.

Next, in response to determining that the plasma density distribution fails to achieve the plasma density distribution criterion, the control unit 122 may cause the microwave power supply 107 and the RF bias power supply 116 to cease output of the second microwave pulse 312 and the wafer bias voltage 352 for a third time period 303 subsequent to the second time period 302. By ceasing output of the second microwave pulse and the wafer bias voltage, the plasma returns to a gas, and etching is no longer performed. In this way, by ceasing output of the second microwave pulse and the wafer bias voltage once the plasma density distribution fails to achieve a desired plasma density distribution criterion, etching that would result in low-uniformity results can be avoided.

It should be noted that the microwave power and wafer bias power for a single cycle of a plasma etching process were described with reference to FIG. 3, but multiple such cycles may be repeated until the desired etching results are acquired.

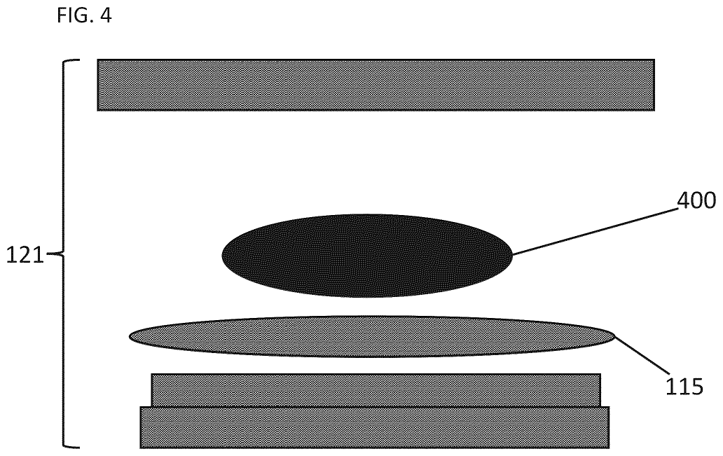

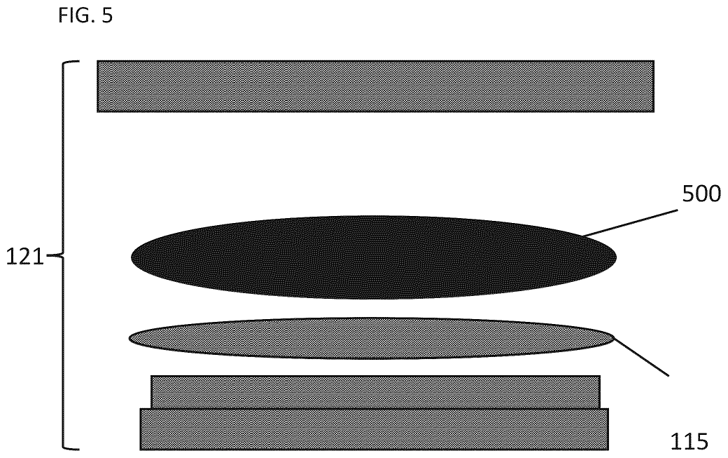

Next, with reference to FIG. 4 and FIG. 5, examples of nonuniform and uniform plasma distributions will be described.

FIG. 4 is a diagram illustrating an example of a nonuniform plasma distribution 400. As described herein, according to conventional lower-power plasma etching techniques, the produced plasma distribution 400 has relatively low density, and does not spread out evenly to the outer periphery of the processing chamber 121 or cover the entire diameter of the wafer 115. Etching performed with such a low-density, nonuniform plasma distribution 400 can lead to nonuniform etching results on the surface of the wafer 115.

FIG. 5 is a diagram illustrating an example of a uniform plasma distribution 500. As described herein, according to the plasma processing technique according to the present disclosure, a high-power microwave pulse is output to produce a uniform plasma distribution 500 that extends evenly to the outer periphery of the processing chamber and covers the entire diameter of the wafer 115. Next, a low-power microwave pulse together with a wafer bias voltage are output to facilitate etching processing, and output of the low-power microwave pulse and the wafer bias voltage are ceased in response to detecting that the plasma density distribution of the plasma in the plasma processing chamber 121 no longer achieves a predetermined plasma density distribution criterion. In this way, by performing plasma etching only when a uniform plasma distribution 500 is present in the processing chamber 121, etching results associated with high uniformity can be obtained.

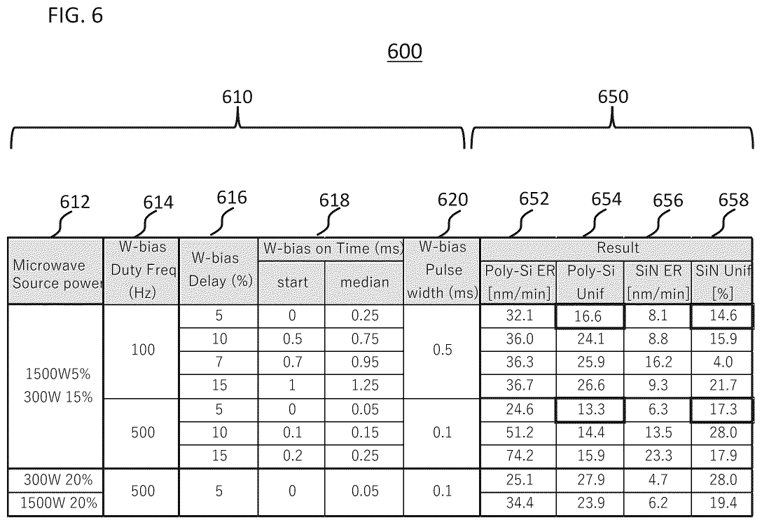

Next, with reference to FIG. 6, an example of plasma processing parameters and corresponding plasma processing results according to the embodiments of the present disclosure will be described.

As described herein, the results of plasma processing can be affected by a number of parameters. For instance, with reference to the plasma processing according to the embodiments of the present disclosure, it is desirable to adjust parameters such as the microwave source power, wafer bias duty frequency, wafer bias delay, wafer bias on-time, and wafer bias pulse width in order to facilitate uniform etching results.

Accordingly, FIG. 6 illustrates a plasma processing table 600 including plasma processing parameters and corresponding plasma processing results, according to the embodiments of the present disclosure.

As illustrated in FIG. 6, the plasma processing table 600 includes a set of plasma processing parameters 610 and a set of plasma processing results 650. In the plasma processing table 600, plasma processing parameters and plasma processing results are illustrated for a first trial in which the microwave source power was set to 1500 W with 5% duty for the first microwave pulse and set to 300 W with 15% duty for the second microwave pulse, and a second trial in which the microwave power was set to 300 W with 20% duty for the first microwave pulse and set to 1500 W with 20% duty for the second microwave pulse.

The set of plasma processing parameters 610 illustrate different parameters that can be controlled or varied to manipulate the properties and behavior of a plasma during plasma processing, and, as illustrated in FIG. 6, may include microwave source power 612, wafer bias duty frequency 614, wafer bias delay 616, wafer bias on-time 618, and wafer bias pulse width 620.

It should be noted, however, that although the plasma processing table 600 illustrates a set of plasma processing parameters 610 that are most relevant to obtaining uniform plasma results with respect to the plasma processing technique according to the present disclosure, the present disclosure is not limited herein, and other plasma processing parameters, such as gas pressure, gas flow rate, electrode configuration, and gas composition can also be suitably adjusted.

Microwave source power 612 is the amount of microwave energy applied to the plasma in the plasma processing chamber. Varying the microwave source power 612 can impact the density and the temperature of the plasma, which can affect the etching rate, selectivity, and uniformity. Higher source power can result in a higher plasma density and temperature, leading to faster etching rates, but it may also increase the likelihood of damage to the substrate or the etched features.

As described herein, aspects of the disclosure relate to applying a first microwave pulse have a first power, and a second microwave pulse having a second power, wherein the first power is greater than the second power. For instance, as illustrated in FIG. 6, the first microwave pulse may have a first power of 1500 Watts and the second microwave pulse may have a second power of 300 Watts. That is, the first power may be five times the second power.

Additionally, each microwave pulse is associated with a duty rate. Here, duty rate refers to the ratio of the on-time of the plasma source (the microwave power) with respect to the total cycle time. In embodiments, the duty rate may be represented as a percentage, where 100% represents continuous or constant application of a specific parameter or condition throughout a full processing cycle. As described herein, aspects of the disclosure relate to applying a first microwave pulse have a first duty rate and a second microwave pulse having a second duty rate, wherein the second duty rate is greater than the first duty rate. For instance, as illustrated in FIG. 6, the first microwave pulse may have a first duty rate of 5% and the second microwave pulse may have a second duty rate of 15%. That is, the second duty rate may be three times the first duty rate.

The wafer bias duty frequency 614 refers to the frequency at which the wafer bias is turned on and off during the etching process. Varying the duty frequency can affect the ion energy and directionality, which can impact the etching rate and selectivity. Higher duty frequency can increase the ion energy, leading to a higher etching rate, but it may also lead to damage or roughness on the substrate surface. As an example, the wafer bias duty frequency for the first microwave pulse may be 100 Hz and the wafer bias duty frequency for the second microwave pulse may be 500 Hz.

The wafer bias delay 616 is the time delay between the start of a plasma processing cycle (e.g., output of the first microwave pulse) and application of the wafer bias voltage. Varying the wafer bias delay can impact the surface activation and cleaning, which can affect the adhesion and the quality of the deposited film or etched features. Longer wafer bias delay can improve the surface activation, but it may also increase the likelihood of sputtering and damage to the substrate surface. As described herein, according to the research of the inventors of the present disclosure, it was found that delaying output of the second microwave pulse with respect to output of the first microwave pulse by a second microwave pulse delay equal to the first duty ratio (e.g., such that the second microwave pulse begins when the first microwave pulse ends), and delaying output of the wafer bias voltage with respect to output of the first microwave pulse by a wafer bias delay that is greater than or equal to the second microwave pulse delay (e.g., such that the wafer bias voltage is output at the same time or later than the second microwave pulse) achieved etching results associated with a high degree of uniformity. This is because, by initiating plasma processing using the second microwave pulse quickly after uniform plasma has been created using the first pulse, etching can be carried out at the time when the plasma density distribution is at its most uniform state.

The wafer bias on-time 618 refers to the duration of time that a wafer bias voltage is applied during the etching process. Varying the wafer bias on-time can affect the ion energy and directionality, which can impact the etching rate and selectivity. Longer on-time can increase the ion energy, leading to a higher etching rate, but it may also lead to damage or roughness on the substrate surface.

The wafer bias pulse width 620 refers to the duration of the individual pulses of the wafer bias voltage applied to the wafer. That is, whereas the wafer bias on-time 618 refers to the total duration of time during which the wafer bias voltage is applied to the wafer, the wafer bias pulse width 620 refers to the duration of individual pulses of the wafer bias voltage applied to the wafer during each cycle. Varying the pulse width can affect the ion energy and directionality, which can impact the etching rate and selectivity. Longer pulse width can increase the ion energy, leading to a higher etching rate, but it may also lead to damage or roughness on the substrate surface.

The set of plasma processing results 650 illustrate different parameters that characterize the etching performance of the plasma etching process, and, as illustrated in FIG. 6, may include Poly-Si etching rate 652, Poly-Si uniformity 654, SiN etching rate 656, and SiN uniformity 658.

It should be noted, however, that although the plasma processing table 600 illustrates a set of plasma processing results 650 that are most relevant to illustrating the uniformity of the etching results with respect to the plasma processing technique according to the present disclosure, the present disclosure is not limited herein, and other plasma processing results can also be monitored and evaluated.

The Poly-Si etching rate 652 refers to the speed at which poly-silicon is removed from the surface of a substrate during the etching process. The etching rate is affected by a number of factors, including the plasma density, gas composition, and substrate bias. Generally, a higher plasma density and a higher substrate bias will result in a higher poly-silicon etching rate. However, a high etching rate may also lead to over-etching or excessive removal of material, which can negatively impact device performance.

Poly-Si uniformity 654 refers to the evenness of the etching process across the surface of the poly-silicon layer. Non-uniformity can result from variations in the plasma density, gas composition, or substrate bias, among other factors. Non-uniformity can result in irregular device performance, reduced device yield, or even device failure. Therefore, achieving high uniformity is one objective in the poly-silicon etching process.

The SiN etching rate 656 refers to the speed at which SiN (silicon nitride) is removed from the surface of a substrate during the etching process. The etching rate is affected by a number of factors, including the plasma density, gas composition, and substrate bias. Generally, a higher plasma density and a higher substrate bias will result in a higher SiN etching rate. However, like with poly-silicon etching, a high etching rate may also lead to over-etching or excessive removal of material, which can negatively impact device performance.

SiN uniformity 658 refers to the evenness of the etching process across the surface of the SiN layer. Non-uniformity can result from variations in the plasma density, gas composition, or substrate bias, among other factors. Non-uniformity can result in irregular device performance, reduced device yield, or even device failure. Therefore, achieving high uniformity is one objective in the SiN etching process.

With reference to the set of plasma processing parameters 610 and the set of plasma processing results 650 included in the plasma processing table 600, it can be seen that for the given trials, the most desirable poly-Si uniformity 654 (16.6, 13.3) and SiN uniformity 658 (14.6, 17.3) were achieved by using a first microwave pulse of with a power of 1500 Watts and a 5% duty ratio, a second microwave pulse with a power of 300 Watts and a 15% duty ratio, a wafer bias duty frequency of 100 Hz and 500 Hz respectively, a wafer bias delay of 5% (e.g., a wafer bias delay equal to the first duty rate), and a wafer bias pulse width of 0.5 ms and 0.1 ms, respectively. Put differently, a first microwave pulse with a power of 5 times that of the second microwave pulse, a duty ratio of one-third that of the second microwave pulse, and a wafer bias delay equal to the first duty rate facilitated uniform etching results.

As illustrated by the plasma processing table 600, by using a first high-power microwave pulse to create a dense, highly uniform plasma in the plasma processing chamber, and subsequently initiating plasma processing using a low-power second microwave pulse and applied wafer bias quickly after the uniform plasma has been created using the first pulse, etching can be carried out at the time when the plasma density distribution is at its most uniform state, leading to etching results associated with high uniformity.

As described herein, aspects of the disclosure relate to first outputting a high-power microwave pulse to produce a uniformly distributed plasma, and then outputting a low-power microwave pulse together with a wafer bias voltage to facilitate etching processing, and ceasing output of the low-power microwave pulse and the wafer bias voltage in response to detecting that the plasma density distribution of the plasma in the plasma processing chamber no longer achieves a predetermined plasma density distribution criterion.

By setting the first microwave power and the first duty ratio so as to achieve a desired high-density, uniform plasma, and setting the second microwave power and the second duty ratio so as to perform low-power plasma etching, a high level of etching selectivity can be achieved while simultaneously reducing damage and facilitating highly-uniform etching results.

In addition, by using a plasma distribution sensor to monitor a plasma density distribution of the plasma in the processing chamber and cease output of the second microwave pulse and the wafer bias voltage in response to detecting that the plasma density distribution of the plasma in the plasma processing chamber detected by the plasma distribution sensor fails to achieve a plasma density distribution criterion, etching with low density that would result in low-uniformity results can be avoided.

Further, by setting the microwave pulse delay of the second microwave pulse with respect to output of the first microwave pulse to the same value as the first duty ratio of the first microwave pulse (e.g., 5%), and setting the wafer bias delay with respect to output of the first microwave pulse to greater than or equal to the microwave pulse delay, the second microwave pulse and the wafer bias voltage can be applied at the same time that the first microwave pulse ends. As a result, it is possible to initiate plasma processing using the second microwave pulse quickly after a uniform plasma has been created using the first pulse, and etching can be carried out at the time when the plasma density distribution is at its most uniform state.

In this way, it is possible to provide a plasma processing technique that is capable of facilitating uniform etching results in low-power microwave plasma processing applications.

As described herein, aspects of the present disclosure relate to the following aspects.

### Aspect 1

A plasma processing apparatus comprising:
a plasma processing chamber;
a substrate stage disposed within the plasma processing chamber and configured to support a substrate;
a microwave power supply coupled to the plasma processing chamber and configured to generate a microwave signal;
a RF bias power supply coupled to the substrate stage and configured to generate an RF bias signal; and
a control unit configured to control the microwave power supply and the RF bias power supply;
wherein the control unit causes:
the microwave power supply to output, in a first time period, a first microwave pulse having a first power and a first duty ratio to produce a plasma that achieves a plasma density distribution criterion in the plasma processing chamber;
the microwave power supply to output, in a second time period subsequent to the first time period, a second microwave pulse having a second power which is less than the first power and a second duty ratio which is greater than the first duty ratio;
the RF bias power supply to apply, in the second time period, a wafer bias voltage with respect to the substrate stage; and
the microwave power supply and the RF bias power supply to cease output of the second microwave pulse and the wafer bias voltage for a third time period subsequent to the second time period.

### Aspect 2

The plasma processing apparatus according to aspect 1, wherein output of the second microwave pulse is delayed with respect to output of the first microwave pulse by a second microwave pulse delay equal to the first duty ratio.

### Aspect 3

The plasma processing apparatus according to either of aspects 1 or 2, wherein output of the wafer bias voltage is delayed with respect to output of the first microwave pulse by a wafer bias delay that is greater than or equal to the second microwave pulse delay.

### Aspect 4

The plasma processing apparatus according to any one of aspects 1 to 3, further comprising a plasma distribution sensor configured to monitor a plasma density distribution of the plasma in the processing chamber, wherein the control unit is configured to cause the microwave power supply and the RF bias power supply to cease output of the second microwave pulse and the wafer bias voltage in response to detecting that the plasma density distribution of the plasma in the plasma processing chamber detected by the plasma distribution sensor fails to achieve the plasma density distribution criterion.

### Aspect 5

The plasma processing apparatus according to any one of aspects 1 to 4, wherein the plasma density distribution of the plasma in the plasma processing chamber is determined to fail the plasma density distribution criterion in a case that an ion density ratio of the first microwave pulse with respect to the second microwave pulse is greater than 1.48×10¹⁷ to 0.95×10¹⁷ ions per cubic meter.

### Aspect 6

The plasma processing apparatus according to any one of aspects 1 to 5, wherein the second duty ratio is three times the first duty ratio.

### Aspect 7

The plasma processing apparatus according to any one of aspects 1 to 6, wherein the first power is five times the second power.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to exemplary embodiments, other and further embodiments of the invention may be devised without departing from the basic scope thereof, and the scope thereof is determined by the claims that follow. The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. “Set of,” “group of,” “bunch of,” etc. are intended to include one or more. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of exemplary embodiments of the various embodiments, reference was made to the accompanying drawings (where like numbers represent like elements), which form a part hereof, and in which is shown by way of illustration specific exemplary embodiments in which the various embodiments may be practiced. These embodiments were described in sufficient detail to enable those skilled in the art to practice the embodiments, but other embodiments may be used and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

### REFERENCE SIGNS LIST

1. Plasma processing apparatus, 101 . . . Vacuum chamber, 102 . . . Shower plate, 103 . . . Quartz top plate, 104 . . . Cavity resonator, 105 . . . Waveguide, 106 . . . Gap, 107 . . . Microwave power supply, 108 Tuner, 109 . . . Microwave pulse unit, 110, 111, 112 . . . Magnetic field generation coil, 113 . . . Evacuation device, 114 . . . Substrate stage 115.

Wafer, 116 . . . RF bias power supply, 117 . . . Matching box, 118 . . . RF bias pulse unit, 119 . . . Gas supply device, 120 . . . High-density plasma, 121 . . . Processing chamber, 122. Control unit, 125 . . . Plasma distribution sensor

1. A plasma processing apparatus comprising:
a plasma processing chamber;
a substrate stage disposed within the plasma processing chamber and configured to support a substrate;
a microwave power supply coupled to the plasma processing chamber and configured to generate a microwave signal;
a RF bias power supply coupled to the substrate stage and configured to generate an RF bias signal; and
a control unit configured to control the microwave power supply and the RF bias power supply;
wherein the control unit causes:
the microwave power supply to output, in a first time period, a first microwave pulse having a first power and a first duty ratio to produce a plasma that achieves a plasma density distribution criterion in the plasma processing chamber;
the microwave power supply to output, in a second time period subsequent to the first time period, a second microwave pulse having a second power which is less than the first power and a second duty ratio which is greater than the first duty ratio;
the RF bias power supply to apply, in the second time period, a wafer bias voltage with respect to the substrate stage; and
the microwave power supply and the RF bias power supply to cease output of the second microwave pulse and the wafer bias voltage for a third time period subsequent to the second time period.

2. The plasma processing apparatus according to claim 1, wherein output of the second microwave pulse is delayed with respect to output of the first microwave pulse by a second microwave pulse delay equal to the first duty ratio.

3. The plasma processing apparatus according to claim 2, wherein output of the wafer bias voltage is delayed with respect to output of the first microwave pulse by a wafer bias delay that is greater than or equal to the second microwave pulse delay.

4. The plasma processing apparatus according to claim 1, further comprising a plasma distribution sensor configured to monitor a plasma density distribution of the plasma in the plasma processing chamber, wherein the control unit is configured to cause the microwave power supply and the RF bias power supply to cease output of the second microwave pulse and the wafer bias voltage in response to detecting that the plasma density distribution of the plasma in the plasma processing chamber detected by the plasma distribution sensor fails to achieve the plasma density distribution criterion.

5. The plasma processing apparatus according to claim 4, wherein the plasma density distribution of the plasma in the plasma processing chamber is determined to fail the plasma density distribution criterion in a case that an ion density ratio of the first microwave pulse with respect to the second microwave pulse is greater than 1.48×10¹⁷ to 0.95×10¹⁷ ions per cubic meter.

6. The plasma processing apparatus according to claim 1, wherein the second duty ratio is three times the first duty ratio.

7. The plasma processing apparatus according to claim 1, wherein the first power is five times the second power.

8. A plasma processing method for a plasma processing apparatus, the plasma processing apparatus including:
a plasma processing chamber;
a substrate stage disposed within the plasma processing chamber and configured to support a substrate;
a microwave power supply coupled to the plasma processing chamber and configured to generate a microwave signal;
a RF bias power supply coupled to the substrate stage and configured to generate an RF bias signal;
a control unit configured to control the microwave power supply and the RF bias power supply; and
a plasma distribution sensor configured to monitor a plasma density distribution of plasma in the plasma processing chamber;
wherein the plasma processing method includes:
outputting, by the microwave power supply in a first time period, a first microwave pulse having a first power and a first duty ratio to produce a plasma that achieves a plasma density distribution criterion in the plasma processing chamber;
outputting, by the microwave power supply in a second time period subsequent to the first time period, a second microwave pulse having a second power which is less than the first power and a second duty ratio which is greater than the first duty ratio;
applying, by the RF bias power supply in the second time period, a wafer bias voltage with respect to the substrate stage;
measuring, by the plasma distribution sensor in the second time period, a plasma density distribution value of the plasma in the plasma processing chamber; and
ceasing, by the microwave power supply and the RF bias power supply in response to detecting that the plasma density distribution value of the plasma in the plasma processing chamber detected by the plasma distribution sensor fails to achieve the plasma density distribution criterion, output of the second microwave pulse and the wafer bias voltage for a third time period subsequent to the second time period.
